(19) United States
(12) Patent Application Publication
(10) Pub. No.: US 2023/0376652 A1
(43) Pub. Date: Nov. 23, 2023

(54) MAGNETRON MAINTENANCE

(71) Applicant: Elekta Limited, Crawley (GB)

(72) Inventors: Anurag GEHLOT, Crawley (GB); Chris Flint, Crawley (GB)

(21) Appl. No.: 18/246,288

(22) PCT Filed: Sep. 23, 2021
(86) PCT No.: PCT/EP2021/076284

§ 371 Date: Mar. 22, 2023

(30) Foreign Application Priority Data
Sep. 23, 2020 (GB) 2015061.1

(51) Int. Cl. G06F 30/27; H01J 9/50

(52) U.S. Cl. CPC G06F 30/27; H01J 9/50

(57) ABSTRACT

Disclosed herein is a computer-implemented method of determining a model for predictive maintenance of a magnetron for a particle accelerator for a radiotherapy device. The method comprises collating lifetime data of each of a plurality of magnetrons; analysing the data to determine a set of values indicative of the need for magnetron replacement; and outputting the set of determined values to form a model for predictive maintenance of a magnetron.

### FIELD

The present disclosure relates to radiotherapy device, and to a method of monitoring a radiotherapy device.

### BACKGROUND

Radiotherapy is an important tool in modern cancer treatment. Radiotherapy devices are large, complex machines, with many moving parts and inter-operating mechanisms. Despite precision engineering and rigorous testing, some component parts of a radiotherapy device may start to degrade over its lifetime. This can sometimes lead to sub-optimal operation and even the occasional safety override.

If at any point during treatment a radiotherapy device starts to function outside of its normal operating parameters, a safety override or “interrupt” occurs, whereby the machine stops delivering radiation to ensure patient safety. Existing methods therefore result in a significant amount of machine down time. Further, servicing of the radiotherapy machine is often scheduled at a time which is inconvenient, or inefficient in terms of both field service engineer resources and the resources of the hospital or other machine owner.

It has been surmised that predictive maintenance and/or remote diagnostic techniques could be applied to radiotherapy machines. Identifying the link between particular data patterns and the particular fault or degrading component is often non-intuitive even for experienced service engineers.

The present disclosure relates generally to developing a predictive maintenance model for a magnetron of a radiotherapy device, and to using the model to determine if a magnetron of a radiotherapy device is nearing the time at which it should be replaced or repaired. To date, no such predictive approach has been possible, and existing methods of servicing and repair of a radiotherapy device require sending a field service engineer to inspect the machine, take measurements from the magnetron, and diagnose and fix the problem.

Regarding magnetron failure, there are a number of different failure modes. A review of 250 Magnetron replacements in the US resulted in 14 different failure modes not including ‘Dead on Arrival’. Categorising the failure modes is a manual process done by interpreting the comments and closure statements on the cases.

Further, there is no process, training or guidance on determining if a magnetron has failed or can be recovered. It is all down to engineer experience. This means that not all magnetron replacements are essential. Replacements are made often without completing tests to verify the new magnetron performance. It would be useful to provide a consistent framework for determine when a magnetron should be replaced.

The present invention seeks to address these and other disadvantages encountered in the prior art by providing a method of determining trends in magnetron failure data for predictive maintenance of a magnetron.

### SUMMARY

Aspects and features of the present invention are described in the accompanying claims.

There is provided a method of determining a model for predictive maintenance of a magnetron for a radiotherapy device, the method comprising: collating lifetime data of each of a plurality of magnetrons; analysing the data to determine a set of values indicative of the need for magnetron replacement; and outputting the determined values to form a model for predictive maintenance of a magnetron.

The method is a computer implemented method.

The model for predictive maintenance comprises the set of determined values.

The magnetrons are magnetrons which have been replaced.

Optionally the data comprises a plurality of measurements from the respective magnetron.

Optionally—the magnetron is comprised in a particle accelerator for generating a beam of radiation; and the plurality of measurements comprises Low Tension, LT, & High Tension, HT, hour history, the LT being hours over the lifetime of the magnetron it has been switched on in a closed state or higher, HT being the number of hours the beam has been on; the LT and HT hour history comprising at least one of: mean X-ray dose rate for all X-ray energies; min, mean & max tuner position for XLOW energy; min, mean & max magnetron filament current & voltage with no energy selected; and min, mean & max magnetron filament voltage for XLOW energy.

Optionally analysing the data comprises determining average values of each of the plurality of measurements.

Optionally the average values comprise at least one of: the average lifetime of the parts of the magnetron; the average start value and the average end value of the magnetron tuner; the average lifetime of the tuner; the average total MUs delivered by the magnetron; the average HT hours at replacement; the average the average number of days in the magnetron's lifetime; and the average operational hours in a day.

Optionally analysing the data comprises determining trends in the data.

Optionally analysing the data comprises using artificial intelligence to determine trends in the data.

Optionally collating data comprises retrieving data from records stored in a system.

Optionally collating data comprises receiving data from the magnetron over a network.

Optionally the method further comprises receiving data relating to a first magnetron, comparing the data from the first magnetron to the predictive maintenance model; based on the comparison, determining whether replacement should be scheduled.

Optionally the data relating to the first magnetron is received from the first magnetron over a network.

Optionally data relating to the first magnetron comprises a plurality of measurements of the first magnetron; and comparing the data from the first magnetron to the predictive maintenance model comprises comparing each measurement of the first magnetron to a respective value in the model. Optionally comparing the data from the first magnetron to the predictive maintenance model comprises comparing a measurement in the data from the first magnetron to a threshold value in the predictive model, and if the value is greater than the threshold value, determining that replacement of the magnetron should be scheduled.

Optionally the method further comprises outputting the determination.

Optionally outputting the model for predictive maintenance of a magnetron comprises outputting the model to a user interface or to a computer storage medium.

Optionally the method is for determining a model for predictive maintenance of a magnetron in a linear accelerator, and wherein the plurality of replacement magnetrons are magnetrons in a linear accelerator.

There is also provided a computer readable medium comprising instructions which, when executed by a processor, cause the processor to perform the method disclosed herein.

There is also provided a method of determining the power set-up of a magnetron comprising: measuring the magnetron power setup; comparing the measured magnetron power to a predetermined range; if the power is outside the range, adjusting the power to within the specification.

Optionally the following measurements of magnetron power include at least one of M.Mag, Chargerate, Low Dose Interlock, and Cal Block PRF.

### BRIEF DESCRIPTION OF THE DRAWINGS

Specific embodiments are described below by way of example only and with reference to the accompanying drawings in which:

FIG. 1 illustrates a radiotherapy device according to an aspect of the disclosure;

FIG. 2 illustrates a method of determining a predictive maintenance model for a magnetron;

FIG. 3 illustrates a method of predicting a fault in a magnetron in a radiotherapy device system according to an aspect of the disclosure;

FIG. 4 illustrates a block diagram of a radiotherapy device; and

FIG. 5 illustrates a method of reviewing a magnetron power setup.

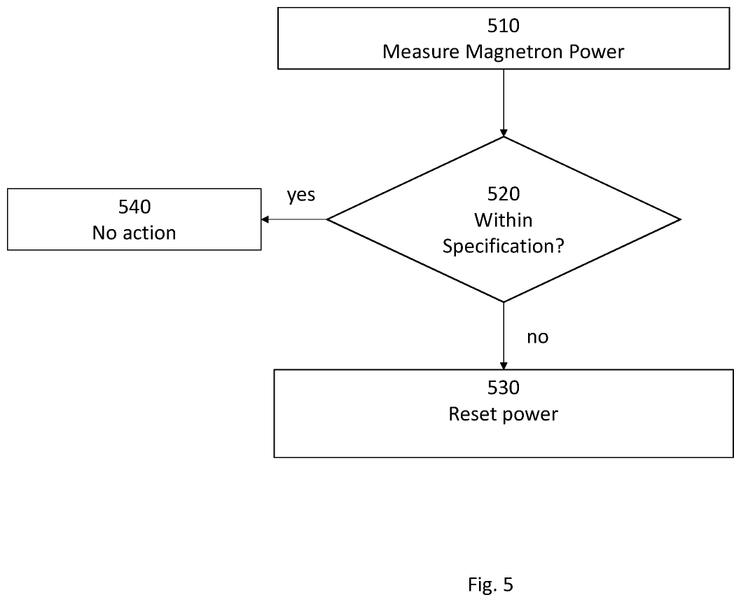

### SPECIFIC DESCRIPTION OF CERTAIN EXAMPLE EMBODIMENTS

Magnetrons and methods in this disclosure may be used in combination with the magnetrons and methods described in to GB patent application number GB1903820.7, entitled MAGNETRON FOR A RADIOTHERAPY DEVICE filed on 20 Mar. 2019, and the corresponding priority-claiming PCT application number PCT/EP2020/057706, the contents of which is incorporated by reference in its entirety.

Radiotherapy devices are an important tool in modern cancer treatment. Radiotherapy devices are large, complex machines, with many moving parts and inter-operating mechanisms. Despite precision engineering and rigorous testing, some component parts of a radiotherapy machines may start to degrade over the lifetime of the machine. This can sometimes lead to sub-optimal operation and even the occasional safety override.

If at any point during treatment a radiotherapy device starts to function outside of its normal operating parameters, a safety override or “interrupt” occurs, whereby the machine stops delivering radiation to ensure patient safety. Such an event is inconvenient, as it adds time to the treatment, and in some cases means the treatment session must finish prematurely. Unplanned equipment downtime can disrupt planned treatment schedules, and may be expensive for the owner, be it due to loss of revenue, servicing and repair costs, or both.

Magnetrons are complex components of a radiotherapy device, which are difficult and expensive to replace. There are a number of reasons a magnetron is replaced:
Unable to achieve specific dose rate
Age of Magnetron
Configuration of Power Conditions.
Tuner Position Above set limit
Noise found on Magnetron scope traces
Ringing at end of Mag I Pulse.

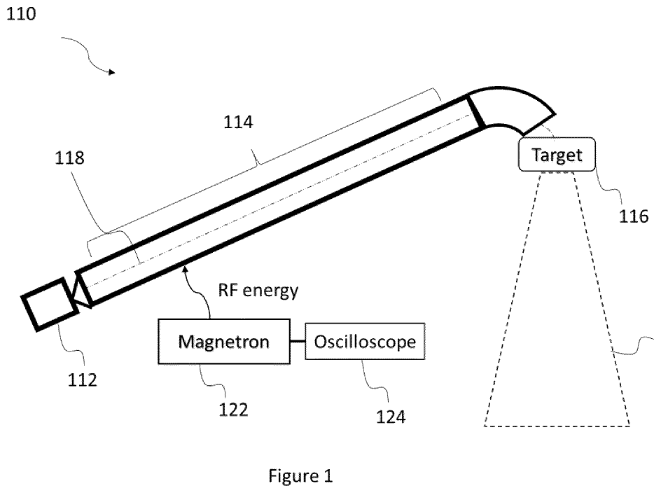

A high-level overview radiotherapy decide according to the disclosure is illustrated in FIG. 1. The linear accelerator 110 includes a source of electrons 112, a waveguide 114, and a target 116. Electrons are emitted from the electron gun and accelerated through the waveguide along an acceleration path 118 which is coincident with the centre axis of the waveguide. The electron beam is bent using magnets and strikes the target 116, to produce an x-ray beam 120. The x-ray beam 120 is used to treat a patient.

The source of radiofrequency waves 122, such as a magnetron, produces radiofrequency (RF) waves. The source of radiofrequency waves is coupled to the waveguide, and is configured to pulse radiofrequency waves into the waveguide.

The source of electrons 112 may be an electron gun. The source of electrons is configured to inject electrons into the waveguide 114. The waveguide 114 comprises a plurality of interconnected acceleration cavities (not shown) forming a channel through which the electron beam passes. The injection of electrons into the waveguide 114 is synchronised with the pumping of the radiofrequency waves into the waveguide 114.

The design and operation of the radiofrequency wave source 122, electron source 112 and the waveguide 114 is such that the radiofrequency waves accelerate the electrons to very high energies as they propagate through the waveguide 114 down the acceleration path 118. The waveguide is designed in order that a suitable electric field pattern is produced which accelerates electrons propagating through the waveguide 114.

A magnetron comprises a cathode heated by a filament. A magnetic field causes electrons emitted by the cathode to spiral outward through a cavity. As the electrons pass the cavity they induce a resonant, RF field in the cavity through the oscillation of charges around the cavity. The RF field can then be extracted with a short antenna attached to one of the spokes.

The device further comprises an oscilloscope 124. The oscilloscope is configured to measure the output of the magnetron. The oscilloscope 124 may be a micro-oscilloscope. The oscilloscope 124 is configured to measure current and anode of the magnetron anode.

Predictive Maintenance

Methods of the present disclosure involve analysing data from magnetrons to determine data patterns indicative of failure of a magnetron. These patterns are used to create a predictive maintenance model for determining whether data from a magnetron indicates whether it should be replaced or repaired.

The present disclosure relates to a magnetron or magnetrons which are the source of radiofrequency waves. The magnetron is for a radiotherapy device, and in some embodiments is for a particle accelerator in a radiotherapy device, the accelerator configured to generate a beam of (therapeutic) radiation.

The disclosed methods help to reduce machine downtime and thereby minimise disruption to the machine's normal operation. The disclosed techniques can also be used to more effectively plan machine downtime for times which are more convenient or cost-effective for the owner of the equipment and/or the patients. Data collected from the magnetron can also be used in the future for trending and to learn how a magnetron behaves during its lifespan. Data can also be used in further research and development of magnetrons for radiotherapy devices.

To create a predictive maintenance model requires sufficient data to determine data patterns and trends prior to and at the point of failure. Currently, in radiation therapy there is no data routinely recorded from the magnetron. If the magnetron malfunctions, or another component of the radiotherapy machine malfunctions, an engineer may manually test components of the machine. This may involve testing the parameters of the magnetron through manually, and temporarily, attaching an oscilloscope to the magnetron. This is done during machine “downtime”, i.e. when the machine is not operational. The output parameters and behaviours of the magnetron therefore are only tested or recorded once the radiotherapy machine malfunctions. Unplanned equipment downtime can disrupt planned treatment schedules.

The behaviour of a magnetron over its lifetime is not tracked or recorded. Particularly, conditions a magnetron has been exposed to, or the behaviours of the magnetron, towards the end of its life are not tracked or analysed. There is no known way of identifying magnetrons which are approaching the end of their operational life.

Further, measurements of magnetron output are not taken during routine operation of a radiotherapy device, but are only taken by an onsite service engineer. This will be either during unplanned downtime or planned downtime. Since under normal operation the output of a magnetron is not measured, a magnetron may be operating within a performance range which, whilst acceptable to meeting the performance requirements, is not optimal. Performing outside optimal conditions may lead to a shortening of the life span of the magnetron, or to less efficient or suboptimal performance of the radiotherapy device.

Finally, since measurements of the output of the magnetron can currently only be taken with a service engineer on site, and are not taken during routine operation of the radiotherapy device, there is a lack of data relating to performance of a magnetron in a radiotherapy device over its lifetime. It has to date not been possible to establish patterns relating to the performance of a magnetron. Under the present set up, there is not enough data to determine particular data patterns which may be indicative of a particular fault.

To date there has been no predictive maintenance of a magnetron of a radiotherapy device. For the above reasons the data has not been collected to create a model for predictive maintenance of a magnetron. This disclosure relates to a method of creating a model for predictive maintenance of a magnetron.

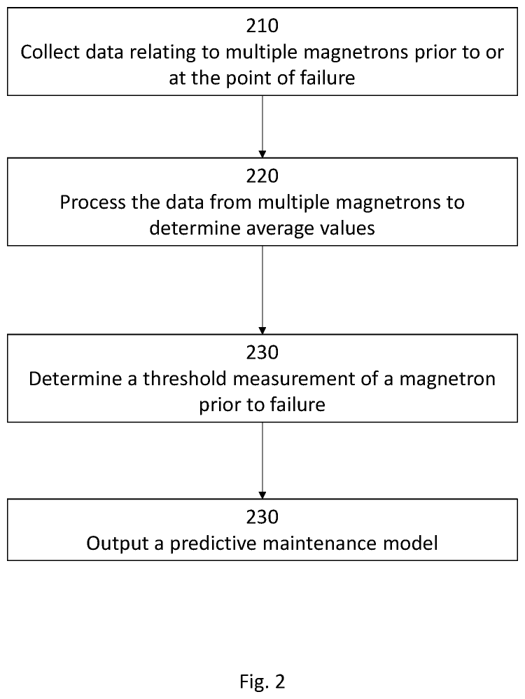

FIG. 2

FIG. 2 shows a method of determining a model for predictive maintenance of a magnetron. The method is a computer-implemented method performed by a processor of a computer or at a central server. The model is based on data from a plurality of magnetrons and can be used to determine whether a specific magnetron has an increased likelihood of failure.

The method includes collating data 210 from multiple magnetrons, the data relating to the magnetron prior to or at the point of failure of that magnetron. In some examples the data is lifetime data from the magnetron. Collating data is obtaining or retrieving data.

In some examples the data is collected through accessing records stored on a system. The records include data relating to a number of measurements from each of a plurality of magnetrons at or prior to failure. In some examples the data is collected through accessing multiple different records stored in multiple different systems. In other examples the data is collected directly from a magnetron. That is, the magnetron includes a component configured to send data relating to the magnetron to a central server via a network.

The lifetime for the magnetron is taken until the magnetron is replaced in the radiotherapy device, or disused, disconnected, or otherwise ends its lifetime of being un use.

The data collected can include values for the following measurements or parameters of the magnetron. Here, the data is referred to as comprising a plurality of measurements or parameters. The ‘measurements’ or refer to a quantity being measured. Therefore the data comprises a plurality of different quantities being measured. The measurement or parameters is the value of that quantity. The measurements may be comprised in, or derived from, the data:

LT & HT Hour History
Mean X-Ray Dose Rate for all XRAY Energies (Not FFF).
Min, Mean & Max Tuner Position for XLOW Energy.
Min, Mean & Max Magnetron Filament Current & Voltage with no energy selected.
Min, Mean & Max Magnetron Filament Voltage for XLOW Energy.
LT Hours—Low Tension Hours is the amount of time the linac has been switched on and in a closed state or higher. The device is in LT state when machine is switched on and no beam is being produced. For LT Hours, essentially the machine is in standby mode and can warm up (Water Temperature increases, power supplies become energised). It is only when the machine is radiating that the Magnetron is ‘on’ (i.e. HT hours).
HT Hours—High Tension Hours is the number of hours which the beam has been on for.

XLOW is the lowest configured XRAY Energy of the radiotherapy device. Depending on machine configuration XLOW could be 4 MV, 6 MV or 8 MV.

The mean X-ray dose rate is the mean dose rate produced by the radiotherapy device and calculated on a daily basis. To avoid start-up values and remain consistent across the install base, it is measured when the beam has delivered more than 50 MU's (Monitor Units) and where dose rate is set to maximum.

The Magnetron Filament Voltage and Current are monitored through data items. When there is ‘no energy selected’ the values revert to default ‘resting’ values, and changes in the default resting values can be tracked over time. No Energy Selected is time when the magnetron is on but an beam energy has not been selected. For example, when the machine is turned on at the start of the day and where no beam data to be delivered has been loaded.

The magnetron is comprised in a radiotherapy device. The radiotherapy device produces a beam of radiation which is delivered to a patient during treatment. The beam or radiation comprises high-energy x-rays, and the magnetron is an essential component in producing the beam of radiation as described above in relation to FIG. 1. The mean x-ray dose is the mean dose of x-rays produced by the radiotherapy device over the lifetime of the magnetron.

After collecting the data, the method includes analysing the data to determine a set of values indicative of the need for a review of the setup to avoid future failure. In the method of FIG. 2 this is done is steps 220 and 230.

Values indicative of the need for magnetron replacement are derived from the measurements prior to or at the point of failure. The values represent values which, if displayed by the magnetron, can output of a magnetron in the time shortly or immediately before a magnetron reaches the end of its lifetime.

The predictive maintenance model comprises values indicative of the need for magnetron maintenance. The values in the indicative of the need for magnetron replacement which are included in the model are based on the measurements comprised in the data.

At step 220 the method includes processing the data to determine average values of each measurement of the plurality of magnetrons prior to or at the time the magnetron is replaced. The magnetron comprises a plurality of parts, including a tuner. This can include determining
the average lifetime of the parts of the magnetron;
the average start value and the average end value of the magnetron tuner
the average lifetime of the tuner
the average total monitor units (Mus) delivered by the magnetron. An MU is a measure of machine output of the radiotherapy device, which is the dose delivered by the beam produced by the radiotherapy device.
the average HT hours in the magnetron's lifetime
the average number of days since installation of the magnetron in the radiotherapy device (number of days in the magnetron's lifetime)
the average length of operation of the magnetron during a day in use (i.e. in a clinical day)

The magnetron's lifetime is the total time the magnetron has been in use and the tome which data has been collected from the magnetron.

From the data it can be determined when the magnetron has been replaced as the tuner position changes, and on some occasions a change in dose rate is observed.

At step 230 the method includes analyzing trends in the data to determine a predictive maintenance model. The model can include a plurality of sets of values corresponding to or derived from the average values determined in step 220. A predictive maintenance model in some examples includes threshold values. If data relating to a magnetron falls outside the threshold values, this could be an indication that the magnetron is close to failure and needs replacing.

The predictive maintenance model can comprise rule which relate to parameters associated with a magnetron. For example, it can comprise a number of rules, or specifications, relating to the following parameters of a magnetron:
the age of the parts of the magnetron;
the start value and the current value of the magnetron tuner
the age of the tuner
the total monitor units (Mus) delivered by the magnetron
the HT hours in the magnetron's lifetime to date
the age of the magnetron
the average length of operation of the magnetron during a day in use (i.e. in a clinical day)

Analyzing the trends in data may create a model with a number of rules or specifications relating to the above parameters of a magnetron. Examples of a predictive maintenance model are given below.

There are difficulties presented with analyzing the data and using the data for predictions, especially with manually analyzing the data. The tuner position is often random, on the same machine the optimal tuner position will be different for each magnetron fitted, when a magnetron is changed the tuner position can increase or decrease from the previous value. There also appears to be no real limit to the tuner position, it can run at very high values previously thought to be end of life for many months or years.

Many of the difficulties with manual analytic of data are overcome using the application of AI. In some embodiments artificial intelligence (AI) is used to analyze the data to determine values for a predictive maintenance model for a magnetron.

The determined values are output at step 240 as a model for predictive maintenance of a magnetron. The model may be output to a user interface or to be stored in a system.

There is also provided computer readable medium configured to perform the method of FIG. 2.

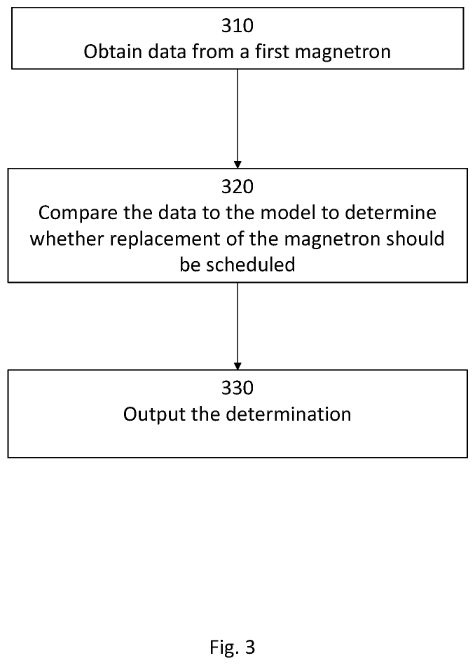

FIG. 3

FIG. 3 illustrates a method of predicting a fault in a magnetron in a radiotherapy device system using the predictive model. The method is a computer-implemented method performed by a processor of a computer or at a central server.

To use the model to determine whether replacement of a magnetron is necessary, data from a first magnetron is obtained 310. The data may be retrieved from records stored in a system.

Alternatively the data may be received from the magnetron at a central server over a network.

The data is then used to determine whether the magnetron has exceeded its expected lifetime.

For example, if the magnetron has exceeded its expected lifetime than it may be required to determine repair or replacement should be scheduled. Alternatively the magnetron may be monitored. In another scenario, it may be determined that a magnetron is not near to the end of its lifetime and that it can continue to operated. If the data indicates that the magnetron is operating outside of its optimal parameters defined in the model, the process determines if a magnetron has exceeded expected lifetime.

For example, each of the average values for measurements may be output as a predicative maintenance model. The values can be used to determine the current lifespan of the magnetron.

Given that the collated data from the replaced magnetrons is collected at the end of the magnetron's life time (at or just prior to the point of failure) it may be desirable for the model to comprise values which correspond to measurements from a magnetron at a time prior to failure.

This means the model can be used to identify magnetrons which will are likely to fail at some point in the near future (i.e. the model can be used are a forewarning rather than notification of imminent failure). To generate, calculate or determine values for the predictive maintenance model, a calculation based on the average values may be used.

A predictive maintenance model can include at least one threshold for a measurement of the magnetron. The values in the model may reflect the measurements comprised in the data (for example, the model could be made from the measurements from one magnetron at the point of failure). Alternatively the model could comprise values calculated form the averages, for example when a quantity reaches 90% of the average value, it may be an indication that the magnetron is close to the point of failure. Therefore a calculation based on the average values could be output as values for a predictive maintenance model.

The model could comprise values which are percentage of the average values, such as 90% of the average values, 95% of the average valued, 98% of the average values, etc.

In some implementations, the lifetime values from the magnetrons is analysed other ways to determine values for a predictive maintenance model. For example, the data might be analysed to determine trends in the measurements from the magnetrons. A trend might be links between different measurements in the data. For example, it might be noticed that a high number of magnetrons fail when two numbers in combination are over a certain value. Analysis such as this can be used to, based on the data from the magnetrons or the averages as calculated in step 220, determine a set of values which indicate that the magnetron setup should be reviewed to extend the lifetime and reduce risk of future failure. The set of values forms the predictive maintenance model, and may be a set of values which each correspond to a measurement of the magnetron (for example, if any of the measurements exceed a respective value combined in the is a value).

There may be multiple sets of values comprised in the model. For example, the model may include values corresponding to different quantities to be measured, which, if achieved in combination indicate a likelihood of failure. For example, a model may specify that repair should be scheduled if:
two specific quantities exceed a respective value (for example the age of the magnetron and the total Mus delivered by the magnetron are each above a respective value), or
any one of the measured quantities exceeds a respective value; or
a first specific quantity is within a specified range, and a second given quantity exceeds a threshold (the total Mus delivered is between two values and the magnetron tuner is over 3 years old).

The skilled person will understand that any number of values could be included in a predictive maintenance model. Values are determined such as through calculations as described above which can form a model which can specific any number of scenarios in which a magnetron should be determined as being ready for replacement. The model can define rules and combinations of measurements or thresholds which readings from a live magnetron can be compared to determine whether the magnetron is ready for repair. The model can be thought of as a number of requirements which if any are met indicate the need for replacement. The skilled person will understand that a model may be complex, or simple. The values within a model are based on values collated form a plurality of magnetrons prior to or at the point of failure.

AI might be used to analyse the data obtained in step 210. AI can determine trends and determine a set of values for measurements on a magnetron which are indicative that a magnetron will fail.

The model may include threshold values against which data from the first magnetron is compared. The data from the first magnetron includes a plurality of measurements, each of those measurements is compared against a respective value in the model. The plurality of measurements refers a plurality of quantities being measured. Each measurement is compared against a respective value, meaning each quantity being measured is compared to a value for that quantity. For example, the measurement of LT & HT Hour History of X-Ray Dose Rate for the first magnetron is compared to a corresponding threshold value for this measurement in the model. The data may be used to derive the measurements of the first magnetron.

The determination can be made dependent on the whether the measurement is above or below the corresponding threshold value in the model. The model may also include predetermined ranges. If the first magnetron measurement is in the predetermined range, the determination is made that replacement of the magnetron does not need to be scheduled. If the measurement of the first magnetron falls outside the predetermined range it is determined that replacement of the magnetron should be scheduled.

The parameters relating to the first magnetron might include: the age of the parts of the magnetron; the start value and the end value of the magnetron tuner; the age of the tuner; the total MUs delivered by the magnetron; the HT hours in the magnetron's lifetime to date; the age of the magnetron; and the average operational hours in a day of the magnetron.

These might be compared to rules or values in the predictive maintenance as follows. If the predictive maintenance model includes a rule relating to the age of the magnetron in combination with the total MUs delivered by the magnetron, the first magnetron parameters (the age of the first magnetron and the total Mus delivered by the first magnetron) are compared to the rule and it is determined whether the magnetron should be replaced. The parameters for the first magnetron are compared to the predictive maintenance model. If it is determined, based on the comparison, that the magnetron does not meet the rules or specifications in the model, it is outputted that replacement should be scheduled.

Finally, at step 330 the determination is output. This may be in the form of an automated message being sent to a service engineer. When this information is analysed it can trigger automatic messages for service engineers and managers to perform a service intervention on the affected machine/s. If the magnetron is showing signs of deterioration, the engineer receives an automated message which prompts him to replace the magnetron. This can be scheduled outside clinical hours to minimise clinical downtime. Scheduling activities outside of clinical hours can also reduce travel time, as well as the mean time to repair. The output may be in the form of an automated message.

There is also provided computer readable medium configured to perform the method of FIG. 3.

### Advantages

Being able to predict a magnetron failure allows the service teams to plan the activity with the customer rather than resulting in unplanned system downtime. The predictive model also validates whether a magnetron replacement is required. This avoids magnetrons being replaced without it being necessary. Finally, it can improve visibility of stock.

In some instances, data is received from the magnetrons at a server over a network.

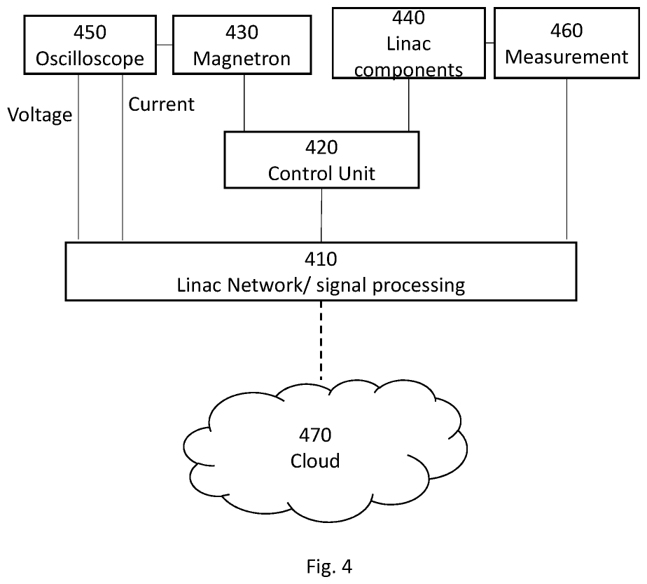

FIG. 4 illustrates a block diagram of a linear accelerator network which optionally can be used in the above implementations. The network of FIG. 4 can be used in the method of the present disclosure when data relating to multiple magnetrons (step 210) and data relating to the first magnetron (step 310) is received from the magnetrons themselves over a network. The connections between components are wired electrical connections. In some embodiments the connections may be wireless.

The linear accelerator has a control until 420 which is configured to control the linear accelerator to deliver a treatment plan to a patient. The control until 420 controls the magnetron 430 to output a required amount of rf energy to the waveguide. The control unit 420 also controls the other components of the linear accelerator 440. Controlling the other components 440 can include: controlling the electron gun to feed electrons to the waveguide; controlling the gantry to rotate according to the treatment plan to provide the angle which radiation is delivered to the patient; and controlling a collimator, such as a multi leaf collimator, MLC, to collimate the beam according to the treatment plan.

The control unit 420 sends information on the linac network 410. The linac network 410 may send the treatment plan to the control unit 420 ahead of the treatment delivery.

The magnetron 440 is controlled by the control unit to 420 to provide rf energy to the waveguide of the linac. The output of the magnetron 430 is measured by oscilloscope 450. The oscilloscope may send the measurements to the linac network. The measurements may be sent through wired or wireless connections to the linac network. The oscilloscope may be a headless oscilloscope which sends the data to an ARM based micro-computer. This micro-computer is connected to the linac network.

The control 420 also controls other components 440 of the linac, for example the electron gun, the gantry and/or the multi-leaf collimator. Outputs of each of these components are sent to the linac network 410. The outpours are measured by different measurement devices. The output of the beam itself may also be measured, and the measurement sent to the linac network 440. The measurements of the beam and of the outputs of the components of the linac are sent to the linac network as electrical signals through an electrical connection, or are sent wirelessly.

The linac network 410 has a wireless connection to the internet. The linac network can send information to a central server such as Axeda or Thingworx. The data can then be automatically analyzed and stored.

The data may be sent—that is transmitted—over a wireless network such as an internet or intranet, WLAN connection or a peer-to-peer connection. Data from the linac network can be sent to a central server storage. The central server, such as a cloud solution, can be accessed remotely, for example from a computer at a central location which is also connected to the internet. That is, the linac network is configured to send data to the central server, and data on the central server can be accessed from a device which is located at a location remote from the linear accelerator.

The data which is transmitted to the cloud in the system of FIG. 2 includes:
The treatment plan (including the dose of radiation, the shape of the radiation beam, the angles at which the radiation is delivered, the timing of pulses of radiation and any other information relating to the delivery of radiation)
The history of the magnetron—including LT and HT hours for a plurality of measurements
The output of other components of the linear accelerator

Magnetron Power Set Up

There is also provided a method of analysing magnetron power set-up.

The present inventors have determined that if a machine runs with abnormal power, more frequent replacements are required. The inventors have determined that machines with two or more energies (for example XRays or High energy electrons—15 MeV+) running with abnormal power conditional would have double the rate of magnetron replacements compared to machines running within expected ranges. A single energy machine (e.g. 6 MV) where power conditions are outside the set thresholds become 25% more likely to have a magnetron fail.

Magnetron power should be set up appropriately to ensure optimum performance of the magnetron. There is a specification for what the Magnetron Current (Mag I) should be when the magnetron magnet current (M.Mag) is a certain value. When a magnetron is set up, Mag I Pulse is measured on site to determine if the power is set up appropriately. Each magnetron has an optimum range or specification for power set-up. This power setup is controlled by the M.Mag and charge rate, which are known values to be set for each energy. Magnetrons are setup within a specific range of efficiency depending on the value of M.Mag.

The magnetron power can be analysed using one or both of two thresholds. The first is the ratio M.Mag/Chargerate, and the second is a limit to the highest charge rate per energy.

A method of determining the power set-up of a magnetron is described below. The method may be performed by a user. Alternatively the method may be computer implemented.

At step 410 the magnetron power setup is measured. Magnetron setup can be reviewed in the QlikSense application RCC Monitoring.

Measuring the magnetron power set up can include reviewing the setup of one or more energies and sorting by the values of:
M.Mag
Chargerate

M. Mag is the magnetron magnet current. Changing the M Mag parameter changes the strength of the magnetic field around the magnetron. Chargerate is the charge rate of the HT power supply unit.

The power ratio is M.Mag divided by Chargerate. The value of M Mag should be “matched” to the value of charge rate according to a ratio. If these parameters are not matched the magnetron life will be shortened. The combination of M Mag and Chargerate set the magnetron current Mag I.

In some embodiments the following data items may be considered instead or as well:
Low Dose Interlock
Cal Block PRF

Low dose interlock sets the threshold for dose rate. If the beam fails to achieve this value or degrades below it, the beam will terminate abnormally. Cal block PRF can be used to reduce the number of magnetron pulses.

At step 420 the measured magnetron power setup is compared to the specification/designated ranges. The specification is a predetermined range. An example of a specification is as follows

| | Power | Power | Chargerate |
|---|---|---|---|
| Energy | Ratio Low | Ratio High | High |
| 6 MV | 0.90 | 1.00 | 28.50 |

If the power ratio (M.Mag/Chargerate) falls outside the threshold range, or if the Chargerate at a given energy exceeds the threshold, the magnetron power setup is determined to fall outside the specification.

If the magnetron power setup is determined to be outside the designated efficiency ranges or specification, the power is adjusted to within the specification 430, for example to factory settings. Adjusting the power setup to within specification may comprise adjusting one or more of a number of parameters within the machine (for example dose rate, magnetron filament voltage, and others). Adjusting the magnetron power setup to bring the power to within specification puts the magnetron under less strain meaning it is less likely to fail.

If, at step 420, the magnetron power is determined to be within the specification 440, no action is taken.

Therefore there is provided a method of reviewing magnetron power set-up to increase the life span of the magnetron.

Features of the above aspects can be combined in any suitable manner. It will be understood that the above description is of specific embodiments by way of aspect only and that many modifications and alterations will be within the skilled person's reach and are intended to be covered by the scope of the appendant claims.

1. A computer-implemented method of determining a model for predictive maintenance of a magnetron for a particle accelerator for a radiotherapy device, the method comprising:
collating lifetime data of each of a plurality of magnetrons;
analyzing the lifetime data to determine a set of values indicative of a need for magnetron replacement; and
outputting the set of determined values to form a model for predictive maintenance of a magnetron.

2. The method according to claim 1, wherein the lifetime data comprises a plurality of parameters from the respective magnetron.

3. The method according to claim 2, wherein:
the magnetron comprises a tuner and is comprised in a particle accelerator for generating a beam for a radiotherapy device;
the plurality of parameters comprises Low Tension, LT, & High Tension, HT, hour history, the LT hour history being hours over the lifetime of the magnetron it has been switched on in a closed state or higher, HT hour history being a number of hours the beam has been on; and
the LT and HT hour history comprising at least one of: mean X-ray dose rate for all X-ray energies, min, mean and max tuner position for a lowest configured x-ray (XLOW) energy, min, mean and max magnetron filament current and voltage with no energy selected, or min, mean and max magnetron filament voltage for the XLOW energy.

4. The method according to claim 3, wherein analyzing the lifetime data comprises determining an average value of each of the plurality of parameters.

5. The method according to claim 4, wherein the average value comprise at least one of:
an average lifetime of one or more parts of the magnetron, an average start value and average end value of the tuner of the magnetron, an average lifetime of the tuner, an average total monitor units (Mus) delivered by the magnetron an average number of HT hours in the magnetron's lifetime, an average number of days in the magnetron's lifetime, or an average number of operational hours in a day.

6. The method of claim 1, wherein analyzing the lifetime data comprises determining one or more trends in the lifetime data.

7. The method of claim 1, wherein analyzing the lifetime data comprises using artificial intelligence (AI) to determine one or more trends in the data.

8. The method of claim 1, wherein analyzing the lifetime data comprises determining a set of threshold values for the magnetron relating to one or more of: an age of one or more parts of the magnetron, a start value and a current value of a tuner of the magnetron, an age of the tuner, a total number of monitor units delivered by the magnetron, a total number of HT hours in the magnetron's lifetime to date, an age of the magnetron, or an average length of operation of the magnetron during a day in use.

9. The method of claim 1, wherein collating the lifetime data comprises retrieving data from records stored in a system.

10. The method of claim 1, wherein collating the lifetime data comprises receiving data from the magnetron over a network.

11. The method of claim 1, further comprising:
receiving data relating to a first magnetron;
comparing the data from the first magnetron to the model for predictive maintenance; and
based on the comparison, determining whether replacement should be scheduled.

12. The method of claim 11, wherein the data relating to the first magnetron is received from the first magnetron over a network.

13. The method of claim 11, wherein the data relating to the first magnetron comprises lifetime data and a plurality of measurements of the first magnetron and wherein comparing the data from the first magnetron to the model for predictive maintenance comprises comparing each measurement of the plurality of measurements of the first magnetron to a respective value in the model for predictive maintenance.

14. The method of claim 11, wherein comparing the data from the first magnetron to the predictive maintenance model comprises comparing a measurement in the data from the first magnetron to a threshold value in the predictive model, and in response to the value being greater than the threshold value, determining that replacement of the magnetron should be scheduled.

15. The method of claim 11, further comprising:
outputting the determination.

16. The method of claim 1, wherein outputting the model for predictive maintenance of a magnetron comprises outputting the model for predictive maintenance to a user interface or to a computer storage medium.

17. (canceled)

18. A non-transitory computer-readable medium comprising instructions which, when executed by a processor, cause the processor to:
collate lifetime data of each of a plurality of magnetrons;
analyze the lifetime data to determine a set of values indicative of a need for magnetron replacement; and
output the set of determined values to form a model for predictive maintenance of a magnetron.

19. A method of determining a power set-up of a magnetron comprising:
measuring the power set-up of magnetron;
comparing the measured power set-up of the magnetron to a predetermined range; and
in response to the measured power set-up of the magnetron being outside the predetermined range, adjusting the power set-up to be within the predetermined range.

20. The method of claim 19, wherein measuring the power set-up of the magnetron comprises:
measuring a magnetron magnet current (M.Mag) and a charge rate, wherein comparing the measured power set-up of the magnetron to a predetermined range comprises comparing a ratio of the M.Mag to the charge rate to a predetermined ratio.

21. The non-transitory computer-readable medium of claim 18, wherein the lifetime data comprises a plurality of parameters from the respective magnetron, and wherein analyzing the data comprises determining an average value of each of the plurality of parameters.
